(19) United States
(12) Patent Application Publication
(10) Pub. No.: US 2025/0264534 A1
(43) Pub. Date: Aug. 21, 2025

(54) BATTERY EQUIVALENT CIRCUIT GENERATION METHOD AND APPARATUS

(71) Applicant: MONA INC., Jeollabuk-do (KR)

(72) Inventor: Chang Hee SONG, Seoul (KR)

(73) Assignee: MONA INC., Jeollabuk-do (KR)

(21) Appl. No.: 18/444,762

(22) Filed: Feb. 19, 2024

(51) Int. Cl. G01R 31/367; G01R 31/36; G01R 31/389

(52) U.S. Cl. CPC G01R 31/367; G01R 31/3648; G01R 31/389

(57) ABSTRACT

Provided are a battery equivalent circuit generation method and apparatus. An equivalent circuit generation apparatus repeatedly performs an action process of generating at least one equivalent circuit through an agent of a reinforcement learning model and a process of providing a reward based on an error identified by comparing actual impedance data of a battery with predicted impedance data identified through the at least one equivalent circuit until predefined conditions are satisfied, and then outputs an equivalent circuit generated in an action with a largest reward as an equivalent circuit of the battery. The disclosure was supported by the Ministry of Trade, Industry and Energy (Project: P0018425, Project Number (NTIS): 1415187492).

### BACKGROUND

### 1. Field

The disclosure relates to a method and apparatus for generating an equivalent circuit of a battery, and more particularly, to a battery equivalent circuit generation method and apparatus using reinforcement learning.

The disclosure was supported by the Ministry of Trade, Industry and Energy (Project Number: P0018425, Project Number (NTIS): 1415187492).

### 2. Description of the Related Art

Batteries are used in various fields such as electric vehicles and energy storage systems (ESS). Rechargeable batteries (e.g., secondary batteries) deteriorate due to various factors such as a period of use or a usage environment. Batteries with a certain level of deterioration or more need to be replaced. There is a method of measuring the impedance of a battery to determine a state of the battery. However, there is a limit to determining all electrochemical characteristics of the battery only with the impedance. When an equivalent circuit of the battery may be obtained, various characteristics of the battery may be easily analyzed through the equivalent circuit. However, in order to generate the equivalent circuit of the battery, there is an inconvenience of having to measure various electrochemical characteristics of the battery.

### SUMMARY

Provided are a method and apparatus for automatically generating a battery equivalent circuit by using an actual impedance of a battery.

Additional aspects will be set forth in part in the description which follows and, in part, will be apparent from the description, or may be learned by practice of the presented embodiments.

According to an aspect of the disclosure, a battery equivalent circuit generation method performed by an equivalent circuit generation apparatus includes receiving actual impedance data of a battery, performing, by an agent of a reinforcement learning model, an action of generating at least one equivalent circuit, providing, to the agent, a reward generated based on an error identified by comparing the actual impedance data with predicted impedance data identified through the at least one equivalent circuit in an environment of the reinforcement learning model, repeatedly performing the performing of the action and the providing of the reward until pre-defined conditions are satisfied, and outputting an equivalent circuit generated in an action with a largest reward.

According to another aspect of the disclosure, an equivalent circuit generation apparatus includes an input unit configured to receive actual impedance data of a battery, an agent configured to perform an action of generating at least one equivalent circuit, a reward calculation unit configured to calculate a reward based on an error between the actual impedance data and predicted impedance data generated through the at least one equivalent circuit, in an environment of a reinforcement learning model, and an output unit configured to output an equivalent circuit generated in an action with a largest reward.

### BRIEF DESCRIPTION OF THE DRAWINGS

The above and other aspects, features, and advantages of certain embodiments will be more apparent from the following description taken in conjunction with the accompanying drawings, in which:

FIG. 1 is a diagram illustrating an example of an equivalent circuit generation apparatus, according to an embodiment;

FIG. 2 is a graph illustrating actual impedance data, according to an embodiment;

FIG. 3 is a diagram illustrating an example of a reinforcement learning model, according to an embodiment;

FIG. 4 is a flowchart illustrating an example of an equivalent circuit generation method, according to an embodiment; and

FIG. 5 is a diagram illustrating a configuration of an example of an equivalent circuit generation apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, a battery equivalent circuit generation method and apparatus according to an embodiment will be described in detail with reference to the accompanying drawings.

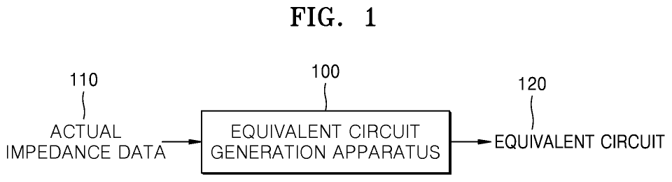

FIG. 1 is a diagram illustrating an example of an equivalent circuit generation apparatus, according to an embodiment.

Referring to FIG. 1, when an equivalent circuit generation apparatus 100 receives actual impedance data 110 of a battery, the equivalent circuit generation apparatus 100 generates and outputs an equivalent circuit 120 of the battery through a reinforcement learning model.

The actual impedance data 110 includes an impedance value measured by applying an alternating current (AC) voltage to the battery. In an embodiment, the actual impedance data 110 may include a plurality of impedance values measured for respective frequencies while applying a plurality of frequencies to the battery. The term “frequency” refers to a frequency of an AC voltage. For example, the actual impedance data 110 may include a first impedance value measured by applying an AC voltage of a first frequency, a second impedance value measured by applying an AC voltage of a second frequency, . . . , and an n^{th} impedance value measured by applying an AC voltage of an n^{th} frequency. In addition, the actual impedance data 110 may include an impedance value of the battery measured through any of various conventional methods, and is not limited to a specific impedance value.

The equivalent circuit 120 is an electric circuit that simulates physicochemical characteristics of the battery. In an embodiment, there is a method of predefining a plurality of equivalent circuit templates, selecting a specific equivalent circuit template according to a type or capacity of a battery, and determining a value of at least one circuit element (e.g., a resistor, a coil, a capacitor, a constant phase element (CPE), or a Warburg diffusion element) existing in the selected equivalent circuit template by using actual impedance data. However, it may be difficult to accurately reflect different physicochemical characteristics of batteries due to various factors such as the type, material, and capacity of the batteries, with a predefined number of equivalent circuit templates. For example, when the same equivalent circuit template is selected for two different types of batteries, the equivalent circuit may not accurately represent a difference in physicochemical characteristics of the two batteries.

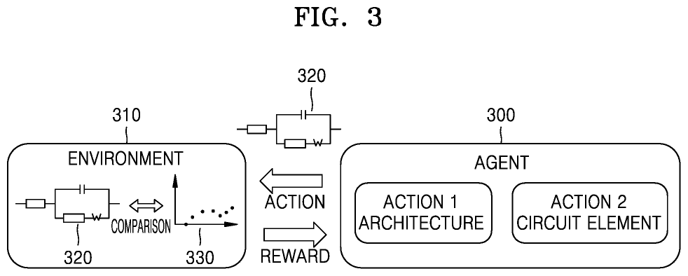

Accordingly, the present embodiment provides a method of generating a structure of the equivalent circuit 120 for each battery by using a reinforcement learning model, rather than a predefined equivalent circuit template, and determining a value of at least one circuit element existing in the structure of the equivalent circuit 120. A method of generating an equivalent circuit by using a reinforcement learning model will be described with reference to FIG. 3.

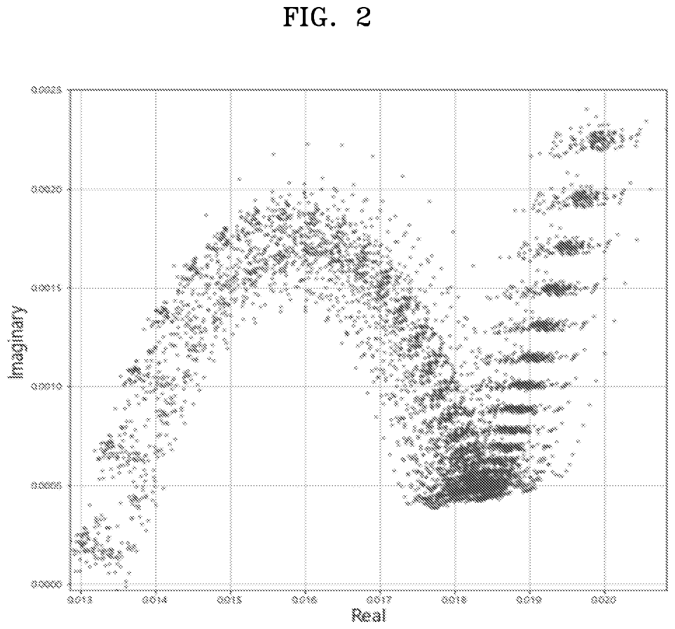

FIG. 2 is a graph illustrating actual impedance data, according to an embodiment.

Referring to FIG. 2, actual impedance data may be measured through electrochemical impedance spectroscopy (EIS). The present embodiment is a graph showing impedance values measured by applying AC voltages of various frequencies between 0.1 Hz and 1000 Hz to a plurality of batteries by using EIS on a complex plane including a real axis and an imaginary axis. The impedance values measured for the plurality of frequencies may be connected to each other and displayed in a curve shape.

FIG. 3 is a diagram illustrating an example of a reinforcement learning model, according to an embodiment.

Referring to FIG. 3, the equivalent circuit generation apparatus 100 generates an equivalent circuit of a battery by using a reinforcement learning model. The reinforcement learning model roughly includes an agent 300 and an environment 310. The agent 300 is a computer program that performs an action in a current state. The reinforcement learning model evaluates a reward by examining validity of the action 300 in the environment 310. In reinforcement learning, learning is gradually performed through repeated interaction between the agent 300 and the environment 310. Because the reinforcement learning model itself including the agent 300 and the environment 310 is already known, how to generate a battery equivalent circuit of the present embodiment by using the reinforcement learning model will be mainly described below.

When the agent 300 receives actual impedance data (i.e., a state of reinforcement learning), the agent 300 performs an action of generating an equivalent circuit 320. A conventional supervised learning method is a method of training an output value of a supervised learning model to match ground truth by using training data that is pre-labeled with the ground truth. However, in the reinforcement learning model of the present embodiment, ground truth does not exist in advance. The agent 300 generates the equivalent circuit 320 based on actual impedance data.

In an embodiment, the agent 300 may perform a first action of determining a structure (architecture) of the equivalent circuit 320 and a second action of determining a value of at least one circuit element existing in the structure of the equivalent circuit 320. The structure of the equivalent circuit 320 may represent an arrangement and a connection structure of the at least one circuit element. For example, the agent 300 may generate an equivalent circuit that connects multiple circuit elements in series and/or in parallel. Although the first action and the second action are separately described to help understanding in the present embodiment, this is merely an example, two actions are not required to be performed, and the agent may generate at least one equivalent circuit 320 in one action.

The equivalent circuit generation apparatus 100 evaluates a reward of the equivalent circuit 320 generated by the agent in the environment 310 of the reinforcement learning model. The environment 310 of the present embodiment is defined to evaluate a reward based on an error identified by comparing impedances. In order to identify an impedance error, first, the equivalent circuit generation apparatus 100 generates predicted impedance data through the equivalent circuit 320 generated by the agent 300. For example, when the actual impedance data 330 includes an impedance value measured for a first frequency, the equivalent circuit generation apparatus 100 generates an impedance value obtained by applying the first frequency to the equivalent circuit 320 and performing analysis as predicted impedance data. That is, the equivalent circuit generation apparatus 100 may generate predicted impedance data by inputting the same frequency component as a frequency component used to measure the actual impedance data 330 to the equivalent circuit 320. Because a method itself of obtaining an impedance value by applying various frequencies to the equivalent circuit 320 is already known, various conventional circuit analysis methods may be applied to the present embodiment.

The equivalent circuit generation apparatus 100 evaluates a reward based on an error identified by comparing the predicted impedance data with the actual impedance data 330 in the environment 310 of the reinforcement learning model. For example, the equivalent circuit generation apparatus 100 may obtain an error between the actual impedance data 330 and the predicted impedance data by using a mean squared error (MSE or L2 loss) or a mean absolute error (MAE or L1 loss). When there are impedance values for a plurality of frequencies, the equivalent circuit generation apparatus may obtain an error based on a difference between an impedance value for each frequency of the actual impedance data and an impedance value for each frequency of the predicted impedance data.

The equivalent circuit generation apparatus 100 may evaluate, as a reward, a value obtained by adding a minus sign to the error. In this case, as the error decreases, the reward increases. In addition, the reward may be defined in various forms according to embodiments. However, the present embodiment is described assuming that a value obtained by adding a minus sign to an error is a reward to comply with the definition of reinforcement learning in which an agent is trained to increase a reward.

The agent 300 performs an action of generating an equivalent circuit again based on the reward received from the environment 310 of the reinforcement learning model. The agent 300 provides the newly generated equivalent circuit 320 to the environment 310 of the reinforcement learning model, and when a reward is received again from the environment 310, repeatedly performs a process of generating the equivalent circuit 320 again. Because reinforcement learning is a learning method that performs an action to increase a reward, the agent 300 may generate an equivalent circuit that outputs predicted impedance data that matches or is almost similar to actual impedance data through repeated execution.

The equivalent circuit generation apparatus 100 may repeatedly perform an action of the agent 300 and reward evaluation in the environment 310 a predefined number of times. For example, the equivalent circuit generation apparatus 100 may terminate the repeated execution when a reward continuously decreases or does not continuously increase beyond a certain threshold value for a predefined number of times. In addition, conditions for terminating the repeated execution may be defined in variously ways according to embodiments.

In another embodiment, the equivalent circuit generation apparatus 100 may further include an element for evaluating and filtering whether the equivalent circuit 320 generated by the agent 300 is an electric circuit that may operate normally. When the equivalent circuit generated by the agent 300 corresponds to an abnormal electric circuit such as a short-circuit or an incorrectly connected polarity of a circuit element, the equivalent circuit generation apparatus 100 may filter the equivalent circuit generated by the agent 300 before evaluating the equivalent circuit 320 in the environment 310. In other words, when the equivalent circuit 320 generated by the agent 300 corresponds to a circuit that operates normally, the equivalent circuit generation apparatus 100 may transmit the equivalent circuit 320 to the environment 310. When the equivalent circuit 320 does not correspond to a normal electric circuit, the equivalent circuit generation apparatus 100 may discard the equivalent circuit 320 without transmitting the equivalent circuit 320 to the environment 310 and then may request the agent 300 again to perform an action of generating the equivalent circuit 320. To determine whether the equivalent circuit is a normal equivalent circuit, various conventional circuit analysis algorithms may be used. Because only a normal equivalent circuit is transmitted to the environment 310 through equivalent circuit filtering, a time taken to identify a reward in the environment 310 may be reduced and thus, a total reinforcement learning time may be reduced.

In another embodiment, the agent 300 may generate a plurality of different equivalent circuits rather than one equivalent circuit 320 in one action. For example, the agent 300 may generate 10 equivalent circuits at one time. The equivalent circuit generation apparatus 100 evaluate the plurality of equivalent circuits in the environment 310 of the reinforcement learning model. For example, the equivalent circuit generation apparatus 100 obtains predicted impedance data for each of the plurality of equivalent circuits, and obtains an error between the predicted impedance data and actual impedance data for each equivalent circuit. Then, the equivalent circuit generation apparatus 100 obtains a reward based on an average of error values of the equivalent circuits. The agent 300 repeatedly performs a process of generating a plurality of equivalent circuits again to increase a reward. The equivalent circuit generation apparatus 100 repeatedly performs an action and a reward until predefined conditions are satisfied, and then outputs an equivalent circuit with a smallest error from among a plurality of equivalent circuits generated in an action with a largest reward as an equivalent circuit of a battery. For example, when a reward for 10 equivalent circuits generated in an N^{th} action is the largest, the equivalent circuit generation apparatus 100 outputs an equivalent circuit with a smallest error value from among the 10 equivalent circuits generated in the N^{th} action as an equivalent circuit of a battery. Because the agent repeatedly performs a process of generating a plurality of equivalent circuits and evaluating a reward thereof at one time, a reinforcement learning time may be reduced compared to a case where one equivalent circuit is generated in one action.

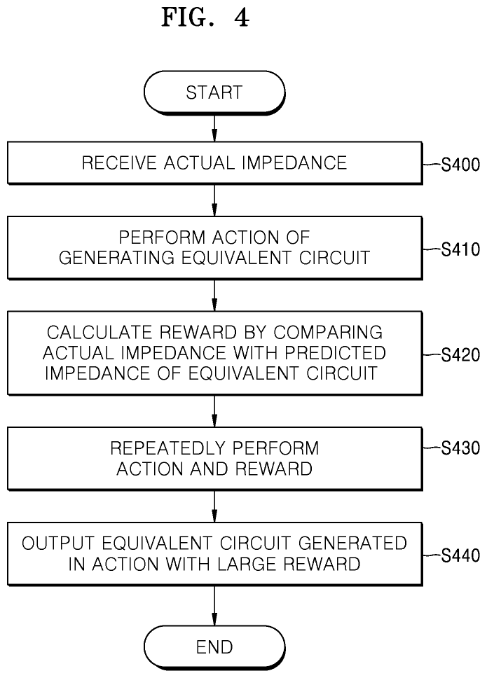

FIG. 4 is a flowchart illustrating an example of an equivalent circuit generation method, according to an embodiment.

Referring to FIGS. 3 and 4 together, the equivalent circuit generation apparatus 100 receives actual impedance data of a battery (S400). The actual impedance data may include a plurality of impedances measured by inputting a plurality of frequencies to the battery. The actual impedance data of the battery may be obtained through EIS, as shown in FIG. 2.

The equivalent circuit generation apparatus 100 generates at least one equivalent circuit through an action of the agent 300 of a reinforcement learning model (S410). For example, the agent 300 may perform an action of generating a structure of an equivalent circuit and assigning a value of each circuit element included in the structure of the equivalent circuit. In another embodiment, the agent 300 may generate one equivalent circuit in one action or may generate a plurality of equivalent circuits in one action. In another embodiment, the equivalent circuit generation apparatus 100 may determine whether the equivalent circuit generated by the agent 300 corresponds to a normal circuit, and when the equivalent circuit is not a normal circuit, may discharge the equivalent circuit and may additionally perform a filtering process of requesting the agent 300 to perform an action again.

The equivalent circuit generation apparatus 100 obtains an error by comparing the actual impedance data with predicted impedance data identified through the equivalent circuit 320 generated by the agent 300 in the environment 310 of the reinforcement learning model, generates a reward based on the error, and provides the reward to the agent 300 (S420). The error between the predicted impedance data and the actual impedance data may be a mean squared error or a mean absolute error.

The equivalent circuit generation apparatus 100 may repeatedly perform operation S410 in which the agent 300 performs an action and operation S420 in which a reward is evaluated in the environment 310 until predefined conditions are satisfied. For example, when a reward continuously decreases or does not continuously increase beyond a certain threshold value for a predefined number of times, the equivalent circuit generation apparatus 100 may terminate the repeated execution.

The equivalent circuit generation apparatus 100 outputs an equivalent circuit generated in an action with a largest reward as an equivalent circuit of the battery. When the agent 300 generates a plurality of equivalent circuits in one action, the equivalent circuit generation apparatus 100 may output an equivalent circuit with a smallest error from among a plurality of equivalent circuits generated in an action with a largest reward as an equivalent circuit of the battery.

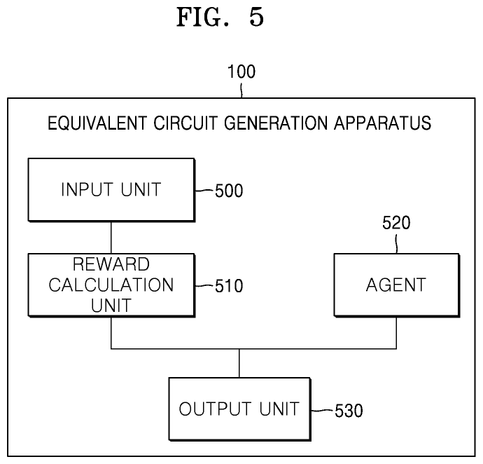

FIG. 5 is a diagram illustrating a configuration of an example of an equivalent circuit generation apparatus, according to an embodiment.

Referring to FIG. 5, the equivalent circuit generation apparatus 100 includes an input unit 500, a reward calculation unit 510, an agent 520, and an output unit 530. The equivalent circuit generation apparatus 100 may be implemented as a computing device including a memory, a processor, and an input/output device, and in this case, each element may be implemented as software, may be loaded into the memory, and then may be executed by the processor.

The input unit 500 receives actual impedance data of a battery. The actual impedance data includes an impedance value measured by applying one or more different frequencies to the battery.

The agent 520 performs an action of generating at least one equivalent circuit in reinforcement learning. For example, the agent 520 may generate a plurality of equivalent circuits in one action.

The reward calculation unit 510 calculates a reward by obtaining an error between the actual impedance data and predicted impedance data generated through the equivalent circuit based on content defined in an environment of the reinforcement learning. When the agent 520 generates a plurality of equivalent circuits in one action, the reward calculation unit 510 may calculate, as a reward, an average of errors between the actual impedance data and a plurality of predicted impedance data generated through the plurality of equivalent circuits.

The output unit 530 outputs an equivalent circuit generated in an action with a largest reward as an equivalent circuit of the battery. When the agent 520 generates a plurality of equivalent circuits in one action, the output unit 530 may output an equivalent circuit with a smallest error from among a plurality of equivalent circuits generated in an action with a largest reward as an equivalent circuit of the battery.

The disclosure may also be implemented as computer-readable code on a computer-readable recording medium. The computer-readable recording medium includes any storage device that may store data which may be thereafter read by a computer system. Examples of the computer-readable recording medium include a read-only memory (ROM), a random-access memory (RAM), a compact disk (CD)-ROM, a magnetic tape, a floppy disk, and an optical data storage device. The computer-readable recording medium may also be distributed over network-coupled computer systems so that the computer-readable code is stored and executed in a distributive manner.

The disclosure has been described with reference to the embodiments thereof. It will be understood by one of ordinary skill in the art that various changes in form and details may be made therein without departing from the spirit and scope of the disclosure as defined by the appended claims. The disclosed embodiments should be considered in descriptive sense only and not for purposes of limitation. The scope of the disclosure is defined only by the following claims, and all the equivalents of the embodiments may also be construed to be in the scope of the disclosure.

According to an embodiment, an equivalent circuit of a battery may be obtained by using an actual impedance value of the battery. Rather than determining a value of a circuit element by using some pre-determined equivalent circuit templates, an equivalent circuit having an optimal structure (architecture) and an optimal circuit element value suitable for characteristics of the battery may be generated. An optimal equivalent circuit suitable for a battery may be automatically generated without needing to define a separate equivalent circuit template whenever a new battery is mass-produced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the disclosure as defined by the following claims.

What is claimed is:

1. A battery equivalent circuit generation method performed by an equivalent circuit generation apparatus, the battery equivalent circuit generation method comprising:
receiving actual impedance data of a battery;
performing, by an agent of a reinforcement learning model, an action of generating at least one equivalent circuit;
providing, to the agent, a reward generated based on an error identified by comparing the actual impedance data with predicted impedance data identified through the at least one equivalent circuit in an environment of the reinforcement learning model;
repeatedly performing the performing of the action and the providing of the reward until pre-defined conditions are satisfied; and
outputting an equivalent circuit generated in an action with a largest reward.

2. The battery equivalent circuit generation method of claim 1, wherein the receiving comprises receiving actual impedance data comprising a plurality of impedances measured by inputting a plurality of frequencies to the battery.

3. The battery equivalent circuit generation method of claim 1, wherein the performing of the action comprises:
generating a structure of an equivalent circuit; and
assigning a value to each circuit element included in the structure of the equivalent circuit.

4. The battery equivalent circuit generation method of claim 1, wherein the providing of the reward comprises calculating a reward based on a mean squared error or a mean absolute error between the predicted impedance data and the actual impedance data.

5. The battery equivalent circuit generation method of claim 1, wherein the repeatedly performing comprises terminating the repeatedly performing when the reward continuously decreases or does not continuously increase beyond a certain threshold value for a predefined number of times.

6. The battery equivalent circuit generation method of claim 1, wherein
the performing of the action comprises generating a plurality of equivalent circuits, and
the providing of the reward comprises providing, as a reward, an average of errors between the actual impedance data and predicted impedance data obtained for the plurality of equivalent circuits.

7. The battery equivalent circuit generation method of claim 6, wherein the outputting comprises outputting an equivalent circuit with a smallest error from among a plurality of equivalent circuits generated in an action with a largest reward.

8. An equivalent circuit generation apparatus comprising:
an input unit configured to receive actual impedance data of a battery;
an agent configured to perform an action of generating at least one equivalent circuit;
a reward calculation unit configured to calculate a reward based on an error between the actual impedance data and predicted impedance data generated through the at least one equivalent circuit, in an environment of a reinforcement learning model; and
an output unit configured to output an equivalent circuit generated in an action with a largest reward.

9. The equivalent circuit generation apparatus of claim 8, wherein
the agent is further configured to perform an action of generating a plurality of equivalent circuits,
the reward calculation unit is further configured to calculate, as a reward, an average of errors between the actual impedance data and a plurality of predicted impedance data generated through the plurality of equivalent circuits, and
the output unit is further configured to output an equivalent circuit with a smallest error from among a plurality of equivalent circuits generated in an action with a largest reward.

10. An non-transitory computer-readable recording medium having recorded thereon a computer program for performing the battery equivalent circuit generation method of claim 1.
